(19) United States
(12) Patent Application Publication
(10) Pub. No.: US 2025/0189240 A1
(43) Pub. Date: Jun. 12, 2025

(54) MICRO-COOLER ASSEMBLIES

(71) Applicants: Toyota Motor Engineering & Manufacturing North America, Inc., Plano, TX (US); Board of Trustees of the Leland Stanford Junior University, Redwood City, CA (US); The Regents of the University of California, Merced, CA (US)

(72) Inventors: Heungdong Kwon, Redwood City, CA (US); Qianying Wu, Redwood City, CA (US); Sougata Hazra, Stanford, CA (US); Mehdi Asheghi, Oakland, CA (US); Kenneth E. Goodson, Portola Valley, CA (US); Ercan Mehmet Dede, Ann Arbor, MI (US); James Palko, Merced, CA (US); Hyoungsoon Lee, Redwood City, CA (US); Daeyoung Kong, Redwood City, CA (US)

(73) Assignees: Toyota Motor Engineering & Manufacturing North America, Inc., Plano, TX (US); Board of Trustees of the Leland Stanford Junior University, Redwood City, CA (US); The Regents of the University of California, Merced, CA (US)

(21) Appl. No.: 18/952,162

(22) Filed: Nov. 19, 2024

Related U.S. Application Data
(60) Provisional application No. 63/608,716, filed on Dec. 11, 2023.

(51) Int. Cl. F28D 15/04; F28D 15/02; F28F 3/02; F28F 3/12

(52) U.S. Cl. CPC F28D 15/046; F28F 3/02; F28F 3/12; F28D 2015/0225

(57) ABSTRACT

In one embodiment, a micro-cooler assembly includes a manifold having at least one inlet for receiving a liquid, a plurality of fins, wherein each fin of the plurality of fins includes a micro-channel, and a plurality of vapor gaps interlaced with the plurality of fins. A width of the micro-channels is graded, and/or a width of the vapor gaps is graded. The micro-cooler assembly further includes a cold plate that includes a surface and a wick region disposed on the surface. The manifold is coupled to the surface of the cold plate. The at least one inlet is operable to provide the liquid proximate the wick region. The liquid is operable to be wicked into the wick region through the micro-channels of the plurality of fins, and heating of the liquid changes phase to a vapor that exits the manifold through the plurality of vapor gaps.

### CROSS-REFERENCE TO RELATED APPLICATIONS

This application claims priority to U.S. Provisional Application No. 63/608,716, filed Dec. 11, 2023, which is herein incorporated by reference in its entirety.

### BACKGROUND

Electronic assemblies, such as microprocessors and power electronics chips, may generate significant heat during operation which requires cooling in order to keep the electronic assemblies within their operating temperature range. Conventional cooling systems can involve passing a cooling fluid across electronic assembles to cool the electronic assembly and maintain the electronic assembly within its operating temperature range.

Micro-coolers may be used to cool electronic devices. In small scale applications, it may be difficult to maintain adequate cooling fluid coverage across the entire micro-cooler, especially at higher temperatures and/or hot spot heat fluxes. Therefore, there exists a need for a micro-cooler for cooling electronic devices which is capable of providing adequate cooling fluid coverage even on a small scale.

### SUMMARY

Embodiments of the present disclosure are directed to micro-cooler assemblies for cooling electronic devices. The micro-cooler assemblies described herein may include a manifold and a cold plate placed on top of an electronic device. Cooling fluid may be flowed through micro-channels formed in the micro-cooler via wicking action. Heat from the electronic device may vaporize the cooling fluid. The vaporized cooling fluid may pass through vapor gaps formed between the microchannels. The cooling fluid may return to a liquid supply to be re-cooled and re-used.

In one embodiment, a micro-cooler assembly includes a manifold having at least one inlet for receiving a liquid, a plurality of fins, wherein each fin of the plurality of fins includes a micro-channel, and a plurality of vapor gaps interlaced with the plurality of fins. A width of the micro-channels is graded. The micro-cooler assembly further includes a cold plate that includes a surface and a wick region disposed on the surface. The manifold is coupled to the surface of the cold plate. The at least one inlet is operable to provide the liquid proximate the wick region. The liquid is operable to be wicked into the wick region through the micro-channels of the plurality of fins, and heating of the liquid changes phase to a vapor that exits the manifold through the plurality of vapor gaps.

In another embodiment, a micro-cooler array includes an array of manifolds and a cold plate. Each manifold includes a plurality of fins, where each fin of the plurality of fins includes a micro-channel. Each manifold also includes a plurality of vapor gaps interlaced with the plurality of fins. The micro-cooler array also includes a central inlet for receiving a liquid centrally disposed within the array of manifolds. The cold plate includes an array of wick regions vertically aligned with the array of manifolds. The cold plate also includes an inlet distribution path positioned between individual wick regions of the array of wick regions. The inlet distribution path includes a plurality of micro-structures. The array of manifolds is coupled to a surface of the cold plate. The central inlet is operable to provide the liquid to a central location with respect to the array of wick regions, and the liquid is operable to be wicked within the inlet distribution path and into the array of wick regions through the micro-channels of the plurality of fins. Heating of the liquid changes phase to a vapor that exits the array of manifolds through the plurality of vapor gaps.

In another embodiment, a micro-cooler array includes an array of manifolds and a cold plate. Each manifold includes an inlet manifold, a plurality of fins, where each fin of the plurality of fins includes a micro-channel and has a right angle shape, and a plurality of vapor gaps interlaced with the plurality of fins. The micro-cooler array also includes a plurality of inlets for receiving a liquid disposed within the array of inlet manifolds of the array of manifolds. The cold plate includes an array of wick regions vertically aligned with the array of manifolds. The plurality of inlets is operable to provide the liquid to the array of wick regions. The liquid is operable to be wicked into the array of wick regions through the micro-channels of the plurality of fins. Heating of the liquid changes phase to a vapor that exits the array of manifolds through the plurality of vapor gaps.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 illustrates a top exploded view of an example micro-cooler assembly according to one or more embodiments described and illustrated herein.

FIG. 2 illustrates a bottom exploded view of the micro-cooler assembly of FIG. 1 according to one or more embodiments described and illustrated herein.

FIG. 3 illustrates an isometric cutaway view of the micro-cooler assembly of FIG. 1 according to one or more embodiments described and illustrated herein.

FIG. 4 illustrates a close-up isometric cutaway view of the micro-cooler assembly of FIG. 1 according to one or more embodiments described and illustrated herein.

FIG. 5 illustrates a top view of another example micro-cooler assembly according to one or more embodiments described and illustrated herein.

FIG. 6 illustrates a plurality of micro-channels having a graded width according to one or more embodiments described and illustrated herein.

FIG. 7A illustrates a first step in a process of fabricating a cold plate according to one or more embodiments described and illustrated herein.

FIG. 7B illustrates a second step in a process of fabricating a cold plate according to one or more embodiments described and illustrated herein.

FIG. 7C illustrates a third step in a process of fabricating a cold plate according to one or more embodiments described and illustrated herein.

FIG. 7D illustrates a fourth step in a process of fabricating a cold plate according to one or more embodiments described and illustrated herein.

FIG. 7E illustrates a fifth step in a process of fabricating a cold plate according to one or more embodiments described and illustrated herein.

FIG. 8A illustrates a first step in a process of fabricating a manifold according to one or more embodiments described and illustrated herein.

FIG. 8B illustrates a second step in a process of fabricating a manifold according to one or more embodiments described and illustrated herein.

FIG. 8C illustrates a third step in a process of fabricating a manifold according to one or more embodiments described and illustrated herein.

FIG. 8D illustrates a fourth step in a process of fabricating a manifold according to one or more embodiments described and illustrated herein.

FIG. 8E illustrates a fifth step in a process of fabricating a manifold according to one or more embodiments described and illustrated herein.

FIG. 9 illustrates an example micro-cooler array according to one or more embodiments described and illustrated herein.

FIG. 10 illustrates an example cold plate of a micro-cooler array according to one or more embodiments described and illustrated herein.

FIG. 11 illustrates another example cold plate of a micro-cooler array according to one or more embodiments described and illustrated herein.

FIG. 12 illustrates another example micro-cooler array according to one or more embodiments described and illustrated herein.

### DETAILED DESCRIPTION

Embodiments of the present disclosure are directed to micro-cooler assemblies for cooling electronic devices. The micro-cooler assemblies described herein may include a manifold and a cold plate placed on top of an electronic device. Cooling fluid may be flowed through microchannels formed in the micro-cooler via wicking action. Heat from the electronic device may vaporize the cooling fluid. The vaporized cooling fluid may pass through vapor gaps formed between the microchannels. The cooling fluid may return to a liquid supply to be re-cooled and re-used.

Conventional micro-cooler assemblies may not provide even fluid distribution across the entire electronic device, especially in small scale applications and/or when the electronic device has localized hot spots. Embodiments can more evenly distribute cooling fluid across the entire electronic device, while effectively evacuating vapor, compared to conventional micro-cooler assemblies.

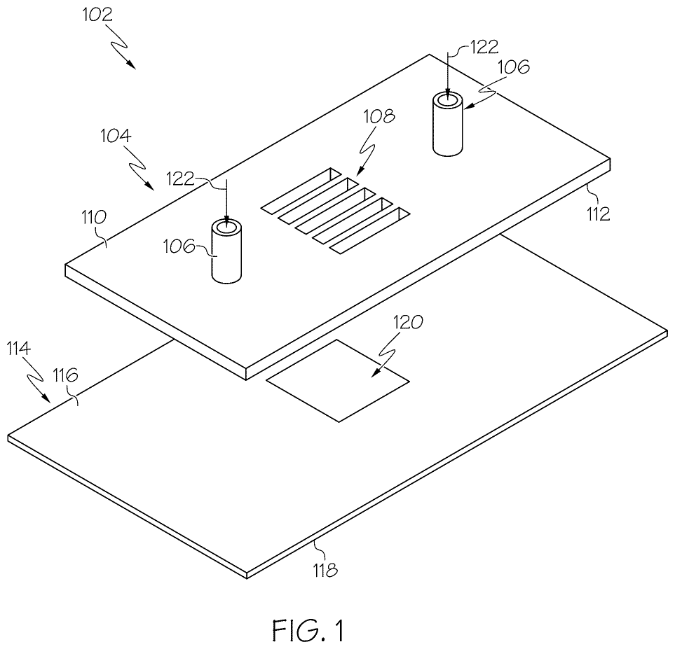

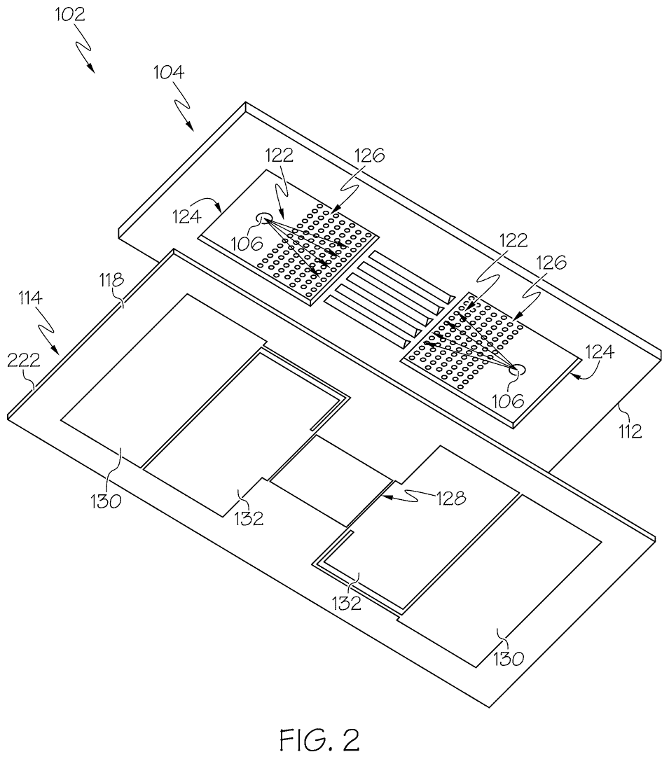

Referring now to FIG. 1, an example micro-cooler assembly 102 is illustrated in an exploded view. The micro-cooler assembly 102 includes a manifold 104 that is coupled to a front surface 116 of a cold plate 114. The manifold 104 may be coupled to the cold plate 114 by any known or yet-to-be-developed methods, such as, without limitation, an adhesive or other bonded interface around the perimeter of the micro-cooler assembly. The front surface 116 of the cold plate 114 includes a wick region 120 that is vertically aligned with a heat generating component 128 on a back surface 118 of the cold plate 114 (see FIG. 2). The wick region is made of a porous material, such as a metal-inverse-opal (MIO) (e.g., a copper-inverse-opal (CIO) structure, nickel inverse opal (NIO) structure, or similar). As described in more detail below, the wick region 120 is operable to receive liquid by capillary force. Both the cold plate 114 and the manifold 104 may be fabricated from silicon, Polydimethylsiloxane (PDMS), or any other suitable substrate or material.

The manifold 104 has one or more inlets 106 operable to introduce a liquid onto the front surface 116 of the cold plate 114. In the illustrated embodiment, the manifold 104 has two inlets 106; however, more or fewer inlets 106 may be provided. The example inlets 106 are cylindrical in shape but embodiments are not limited thereto. The inlets 106 may be configured as couplings operate to receive fluid lines that fluidly couple the inlets 106 to a liquid reservoir (not shown).

The manifold also includes a plurality of vapor gaps 108 interlaced between a plurality of fins 134. The vapor gaps 108 of the illustrated embodiment are configured as slots within the material of the manifold 104; however, the vapor gaps 108 may take on other shapes. Any number of vapor gaps 108 may be utilized depending on the application. As described in more detail below, the vapor gaps 108 are provided to remove vapor generated by the heating of the liquid introduced into the wick region 120 of the cold plate 114 caused by the heat generating component 128, which may be an electronic device, such as a power electronic device or a microchip.

Referring now to FIG. 2, a bottom exploded view of the micro-cooler assembly 102 shown in FIG. 1 is illustrated. In the non-limiting example, the back surface 118 surface of the cold plate 114 includes a variety of electrodes, such as first electrodes 130 and second electrodes 132, which may serve various purposes, such as voltage supply, outputs, control signaling, and the like. A heat generating component 128, such as a power electronic device (e.g., electronic switching device) or microchip (e.g., microprocessor), is coupled to the back surface 118 of the cold plate 114 such that it is beneath the wick region 120 on the front surface 116. Heat created by the heat generating component 128 is transferred through the silicon material of the cold plate 114 and into the wick region 120.

The lower surface 112 of the manifold 104 includes one or more inlet regions 124 fluidly coupled to the one or more inlets 106. In the illustrated embodiment, there are two inlet regions 124 for the two inlets 106. The inlet regions 124 are configured as recesses within the lower surface 112 of the manifold 104 such that a gap is present when the lower surface 112 of the manifold 104 is coupled to the front surface 116 of the cold plate 114. Liquid that is introduced into the inlet regions 124 is then wicked toward the vapor gaps 108 and thus the heat transfer wick region 120. In some embodiments, a micro-pillar array 126 is provided within the inlet regions 124 to further optimize flow and facilitate wicking of fluid toward the heat transfer wick region 120 as well as provide additional surface area for heat transfer.

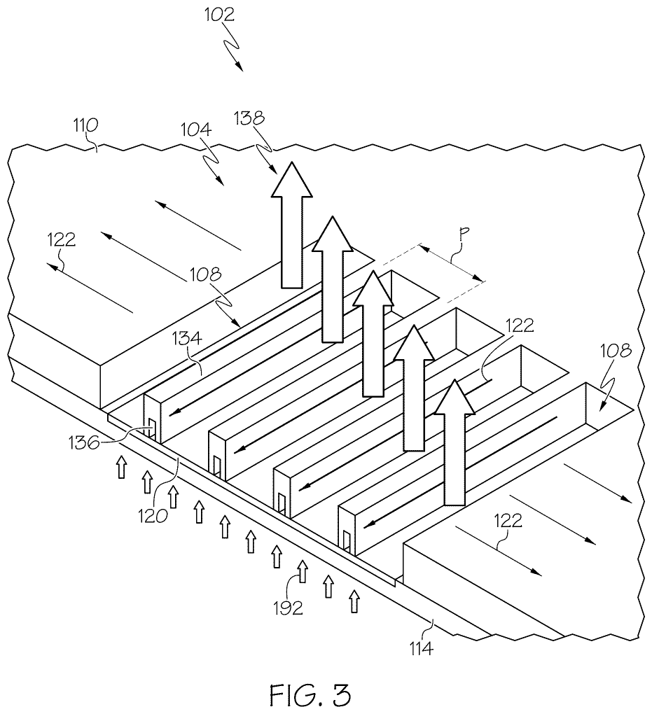

Referring now to FIG. 3, a close-up, cutaway isometric view of the example micro-cooler assembly 102 of FIG. 1 is provided. As stated above, the vapor gaps 108 through the manifold 104 are defined by interlacing fins 134. The fins 134 have a period P that may be constant, or may be graded.

Each fin 134 has a micro-channel 136 that is exposed to the inlet regions 124 to receive liquid 122 as shown by the horizontal arrows. The micro-channels 136 draw the liquid toward the wick region 120 by a wicking capillary force. The liquid 122 is then substantially uniformly distributed along the wick region 120, where it is heated and turned into a vapor 138 by heat 192 generated by a heat generating component. Excess liquid travels laterally across the cold plate 114 and may then exit through drains (not shown), which may be configured as holes within the cold plate 114.

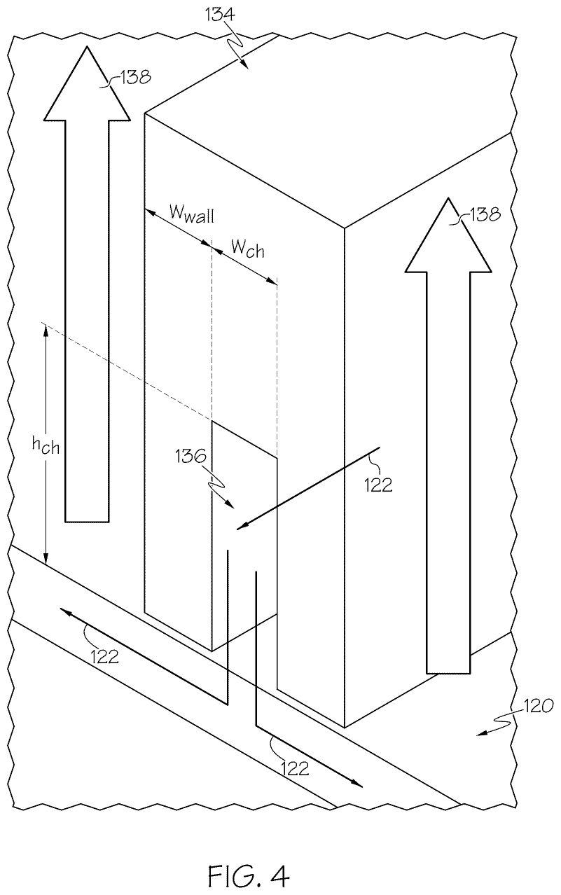

FIG. 4 illustrates a close-up isometric view of an individual fin 134. Cooling liquid wicked through the micro-channel 136, and then is drawn down and across the wick region 120 by capillary force.

As a non-limiting example, the micro-cooler assembly 102 is designed to cool a 0.5 cm×0.5 cm microprocessor footprint area that is designed for efficient liquid delivery and vapor extraction to achieve complete vapor-liquid phase separation or vapor exit quality of approximately 1. The wick region 120 may be configured as a 25 μm thick MIO structure with a 0.5 cm×0.5 cm footprint area. The width of the micro-channel 136 W_{ch} and the width of the fin walls W_{wall} may be 100 μm. The height h_{ch} of the micro-channel 136 may be 300 μm. It should be understood that these dimensions are provided for illustrative purposes only, and that other dimensions may be utilized depending on the application.

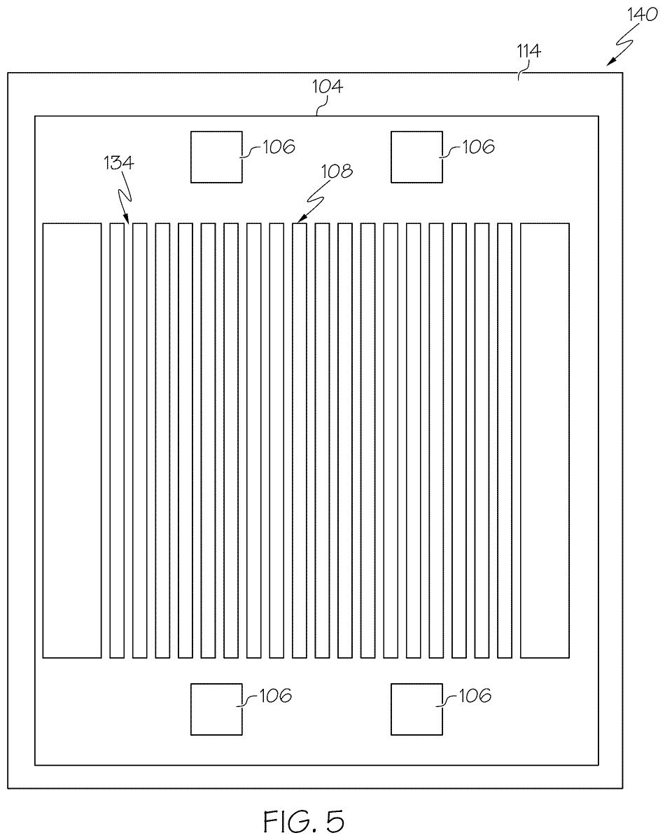

FIG. 5 illustrates a micro-cooler assembly 140 similar to that of FIG. 1 and FIG. 2 except it includes four inlets 106 rather than two. The vapor gaps 108 and fins 134 may be configured in the same manner as described and illustrated with respect to FIGS. 1-4. The additional inlets may be provided when the size of the heat generating component footprint is larger, for example.

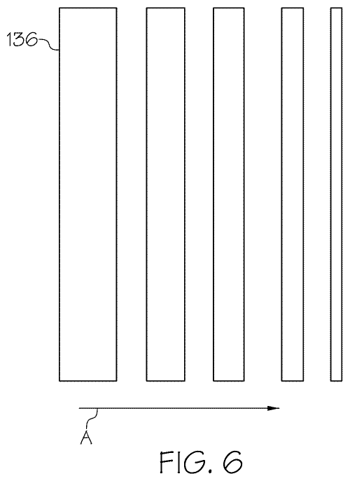

In some embodiments, the width W_{ch} of the micro-channels 136 within the fins 134 may be graded to provide optimal liquid distribution on the wick region. Referring to FIG. 6, the width W_{ch} of the micro-channels 136 decreases in a direction indicated by array A. In other words, the width W_{ch} of the micro-channels 136 may be smaller near the edges of the wick region 120 as compared to the center of the wick region 120, or vice versa. The grading of the width W_{ch} of the micro-channels 136 provides wider micro-channels 136 near the inlets 106 of the micro-cooler assembly 102 and thus an optimal distribution of liquid across the wick region 120. While a specific grading direction is indicated above, any grading direction that is found to enhance fluid wicking and delivery by capillary force may be utilized.

Additionally, the size of the vapor gap 108 (i.e., the width between fins 134) may also be graded. The grading may be provided in any direction to enhance the removal of vapor.

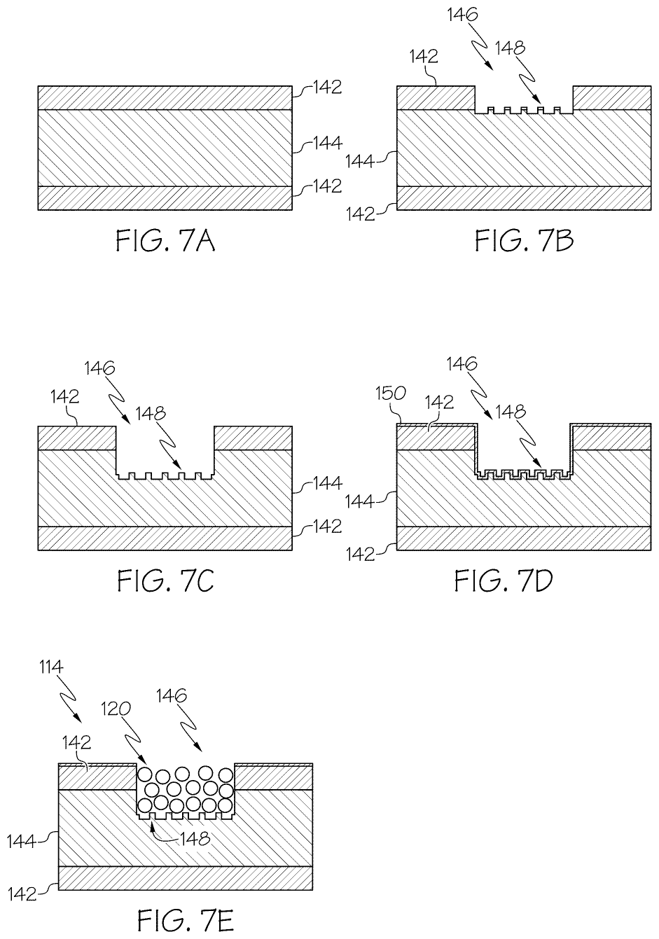

An example non-limiting method of fabricating a cold plate 114 is now described. Referring to FIG. 7A, a silicon substrate 144 having two SiO₂ layers 142 is provided. The SiO₂ layers 142 may be grown or otherwise provided on both sides of the silicon substrate 144 by any known or yet-to-be-developed methods. A photoresist mask (not shown) is provided on one of the SiO₂ layers 142. The exposed SiO₂ layer 142 is then etched, such as by a reactive-ion plasma etcher. The remaining photoresist mask is removed by using acetone, for example. A second layer of photoresist is then provided on the same side of the substrate (e.g., by spin-coating) to form a pin fin array pattern over the same etched area.

Referring to FIG. 7B, the exposed silicon surface through the photoresist is etched to a depth (e.g., 3 μm) using an etching process (e.g., deep reactive-ion etching (DRIE)), creating a thin silicon pin fin array 148. This pin fin array 148 provides support for a latex bead template, preventing its delamination from the silicon surface during the subsequent metal electroplating for the MIO layer. The photoresist residues are removed by immersing the wafer into a solution, such as a Piranha solution.

Next in FIG. 7C, an additional etching of the exposed silicon surface is performed to a depth (e.g., 25-μm) to ensure the top surface of the MIO layer aligns with the silicon wafer surface.

Next, as shown in FIG. 7D, an adhesion layer 150 is applied to the etched surface of the wafer. As a non-limiting example, the adhesion layer 150 may be a thin gold layer (e.g., 100 nm) atop a thin titanium layer (e.g., 10 nm) that is sputtered on the surface of the wafer, including the silicon pin fin array 148, to create a conformal electrode layer.

In FIG. 7E, a MIO layer is electroplated to form the wick region 120 structure. Any known or yet-to-be-developed method for forming the MIO layer may be used. For example, a sacrificial layer in the form of a bead solution (e.g., a sulfate latex bead solution) is applied over the pin fin array 148 and is left to completely evaporate. Once the solution evaporates, the beads form a settled layer, which is then sintered in an oven (e.g., 107 degrees C. for one hour). The sintered bead layer acts as a sacrificial layer for the electroplating of a metal such as copper or nickel. Following the electroplating, the sacrificial layer is dissolved in a solvent (e.g., a tetrahydrofuran solvent), resulting in a permeable porous MIO layer.

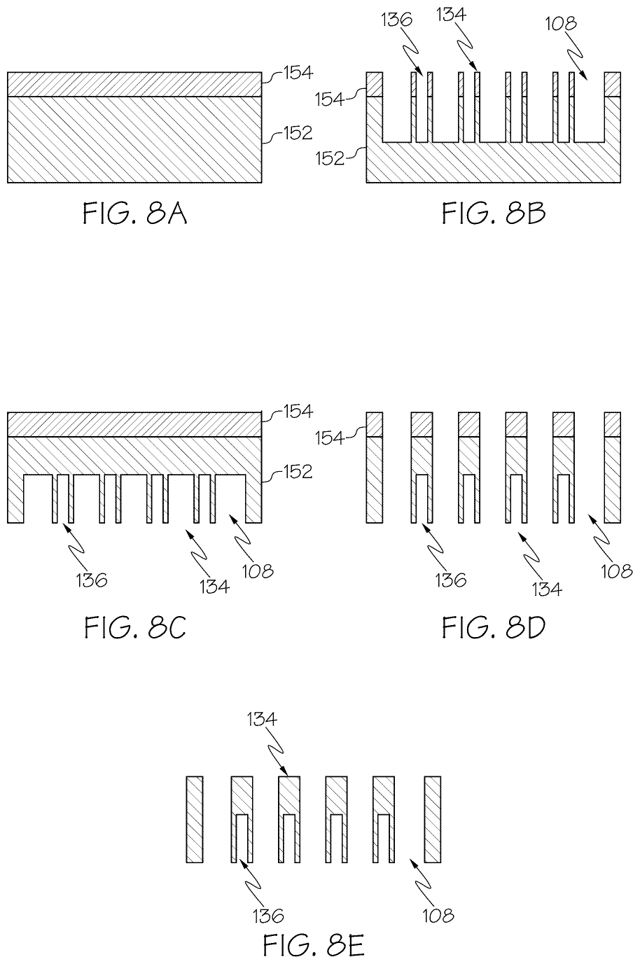

An example non-limiting method of fabricating a manifold 104 is now described. Referring to FIG. 8A, the process starts with a silicon substrate 152 having a photoresist 154 applied to one surface. The photoresist 154 is used to form the vapor gaps 108 and the fins 134.

As shown in FIG. 8B, the silicon substrate 152 is etched to a depth (e.g., 300 μm) to partially form the vapor gaps 108 and the micro-channels 136 within the fins 134. The etching may be performed by DRIE, for example. Any residual photoresist 154 is then removed by immersing the wafer in a solution, such as Piranha solution.

Another photoresist 154 pattern is applied to the backside of the wafer as shown in FIG. 8C. The photoresist 154 is patterned to fully form the vapor gaps 108 through the silicon substrate 152.

An etching process (e.g., DRIE) is performed until the vapor gaps 108 extend fully through the silicon substrate 152, as shown in FIG. 8D.

Finally, any remaining photoresist is removed by immersing the wafer in a solution, such as Piranha solution. The result is shown in FIG. 8E. The inlets 106 may be separate polymer parts that are inserted into or placed over holes (not shown) of the manifold 104 and bonded using a bonding agent such as epoxy.

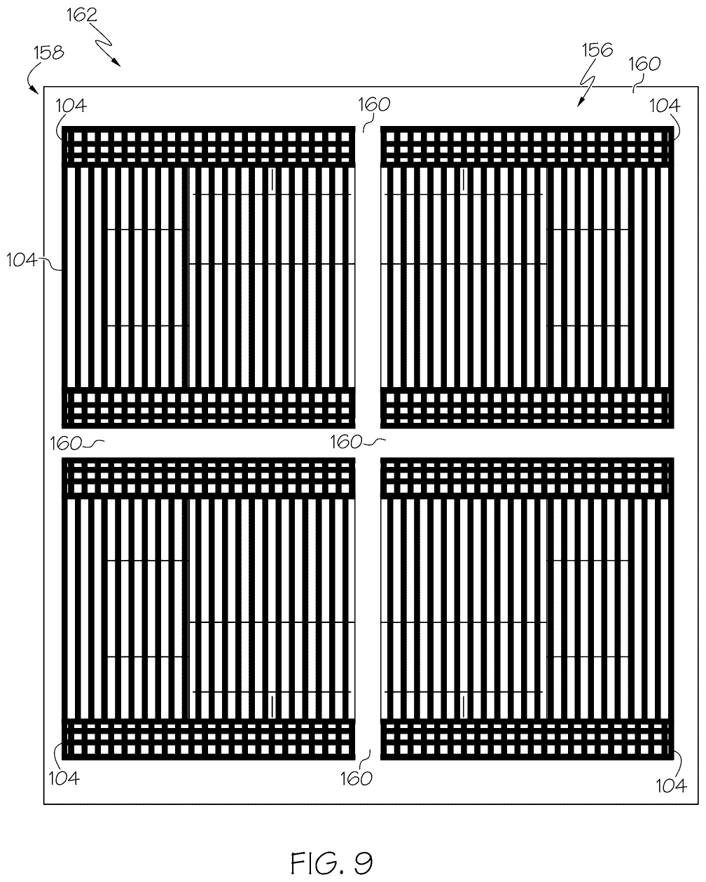

The designs described herein can be tiled together to form a micro-cooler array 162 that is used to cool an electronic device array 156, as shown in FIG. 9. The tiled micro-cooler array 162 includes an array of micro-cooler assemblies 158 defined by an array of manifolds 104 positioned on a cold plate 114, that is further positioned on an electronic device array 156 having a plurality of heat generating components. The cold plate 114 may be a single cold plate 114 or may be an array of individual cold plates 114, for example.

The manifolds 104 have the fins 134 and vapor gaps 108 as described above. Additionally, a wick region 120 is provided on the cold plate 164 beneath each manifold 104. In the illustrated embodiment, an inlet 106 may be centrally provided (not shown) with respect to each of the manifolds 104. Therefore, a single inlet 106 feeds liquid to each manifold 104 and thus each wick region 120 of the cold plate 114 positioned beneath each manifold 104. Additionally, a drainage path 160 is provided between adjacent manifolds to provide an area for excess liquid to flow.

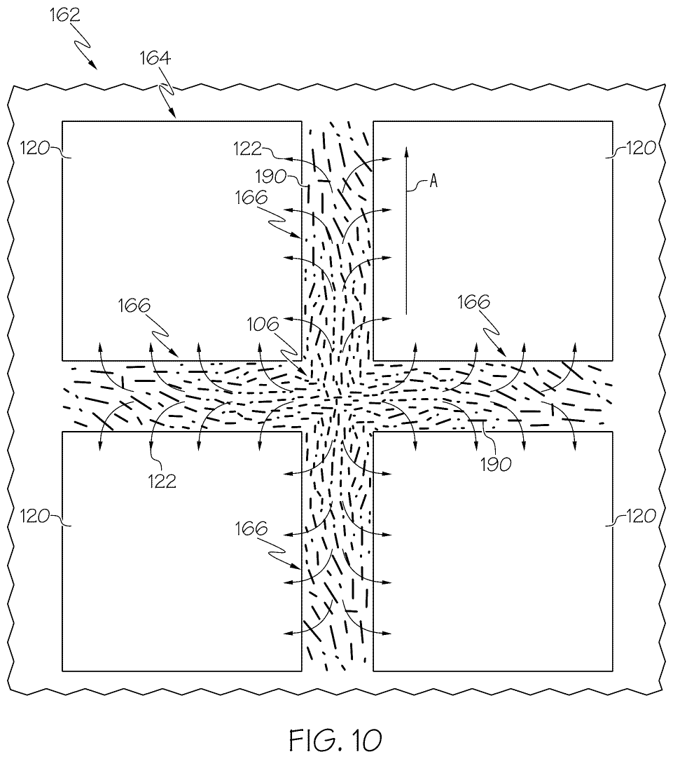

FIG. 10 illustrates the micro-cooler array 162 with the manifold layer removed to illustrate the features of the cold plate 114. The cold plate 164 includes an array of wick regions 120 that is aligned with the array of manifolds 104 shown in FIG. 9. An inlet delivery path 166 is provided between adjacent wick regions 120. The inlet 106 is operable to provide liquid to a central location of the inlet delivery path 166. The inlet delivery path 166 is functionally graded to uniformly route liquid 122 to each wick region 120. For example, the inlet delivery path 166 includes micro-structures (e.g., pillars or similar micro-fins) 190 that are optimally sized, shaped and located to uniformly deliver the liquid to the wick regions 120. As a non-limiting example, the micro-structures 190 may be smaller proximate the inlet 106 and larger further away from the inlet 106. Thus, the micro-structures 190 are functionally graded to provide uniform liquid flow through the inlet delivery path 166. Thus, when liquid reaches the cold plate 164, it flows within the inlet delivery path 166 to the edges of the wick regions 120, where it then enters the micro-channels 136 of the fins 134 and is distributed over the wick regions 120 as described above. While a specific grading direction for the micro-structures 190 is indicated above, any grading direction that is found to enhance fluid wicking and delivery by capillary force may be utilized.

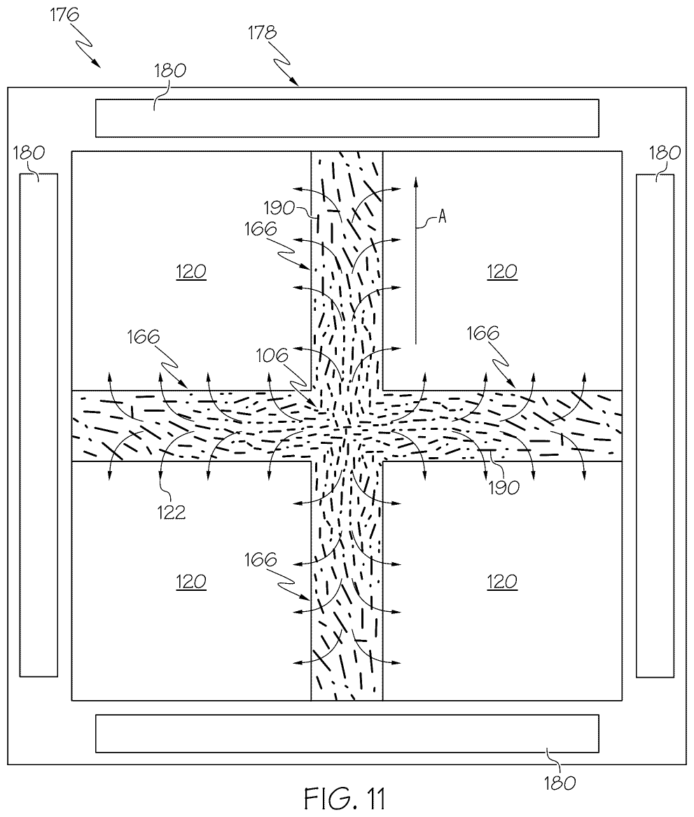

FIG. 11 illustrates another micro-cooler array 176 that is similar to the micro-cooler array 162 of FIG. 10 except there are additional side feeding zones 180 provided at the perimeter of the cold plate 178. These side feeding zones 180 may be configured as additional inlets that provide liquid from the manifold layer, or they may be regions on the cold plate 178 that receive excess liquid flowing from the wick regions 120 that does not change phase to vapor. The side feeding zones 180 may also receive liquid from side inlets (not shown) in some embodiments.

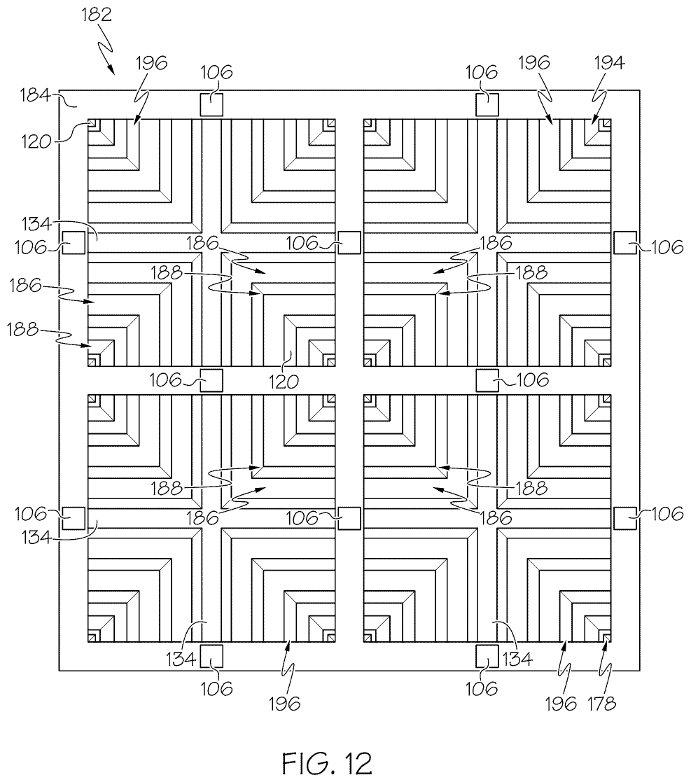

Referring now to FIG. 12, another example tiled micro-cooler array 182 is illustrated. The micro-cooler array 182 includes a top inlet manifold 184 for providing liquid, a middle liquid feed manifold layer 194 and a cold plate 178 having tiled wick regions 120. In this embodiment, the inlets 106 are provided at each side of individual manifolds 196. The inlet manifold 184 surrounds each of the individual manifolds 196. Each individual manifold 196 has four inlets 106 surrounding it. Liquid travels within the inlet manifold 184 and then flows down to the middle liquid feed manifold layer 194 through the inlets 106.

The liquid feed manifold layer 194 includes an array of right angle fins 186 that define an array of right angle vapor gaps 188. Each right angle fin 186 includes a micro-channel 136 (not visible in FIG. 12) as shown in FIG. 3. As shown by FIG. 12, each manifold 196 has four groups of right angle fins 186. Liquid 122 flows from the inlets 106 and then into the micro-channels 136 of the right angle fins 186. In some embodiments, the width of the right angle right angle micro-channels 136 of the right angle fins 186 is graded as shown in FIG. 12. The micro-channels 136 distribute through wicking action the liquid throughout the wick regions 120. The liquid is then heated and turned into a vapor, which then exits through the right angle vapor gaps 188. Excess liquid that is not turned into a vapor may exit through one or more drains (not shown). Additionally, the vapor gap 188 width may also be graded to optimize the removal of vapor.

It should now be understood that embodiments are directed to capillary-assisted micro-cooler assemblies that combine a three-dimensional silicon microchannel manifold with a silicon cold plate having a porous wick structure. Micro-fabrication techniques are used to fabricate the silicon-based microchannel manifold and the cold plate. The microporous wick region has a same area as a heat generating component that is to be cooled.

It may be noted that one or more of the following claims utilize the terms “where,” “wherein,” or “in which” as transitional phrases. For the purposes of defining the present technology, it may be noted that these terms are introduced in the claims as an open-ended transitional phrase that are used to introduce a recitation of a series of characteristics of the structure and should be interpreted in like manner as the more commonly used open-ended preamble term “comprising.”

It should be understood that any two quantitative values assigned to a property may constitute a range of that property, and all combinations of ranges formed from all stated quantitative values of a given property are contemplated in this disclosure.

Having described the subject matter of the present disclosure in detail and by reference to specific embodiments, it may be noted that the various details described in this disclosure should not be taken to imply that these details relate to elements that are essential components of the various embodiments described in this disclosure, even in casings where a particular element may be illustrated in each of the drawings that accompany the present description. Rather, the claims appended hereto should be taken as the sole representation of the breadth of the present disclosure and the corresponding scope of the various embodiments described in this disclosure. Further, it will be apparent that modifications and variations are possible without departing from the scope of the appended claims.

1. A micro-cooler assembly comprising:
a manifold comprising:
at least one inlet for receiving a liquid;
a plurality of fins, wherein each fin of the plurality of fins comprises a micro-channel; and
a plurality of vapor gaps interlaced with the plurality of fins, wherein one or more of a width of the micro-channels and a width of the vapor gaps is graded;
a cold plate comprising a surface and a wick region disposed on the surface, wherein:
the manifold is coupled to the surface of the cold plate;
the at least one inlet is operable to provide the liquid proximate the wick region;
the liquid is operable to be wicked into the wick region through the micro-channels of the plurality of fins; and
heating of the liquid changes phase to a vapor that exits the manifold through the plurality of vapor gaps.

2. The micro-cooler assembly of claim 1, wherein the cold plate is fabricated from silicon and the wick region is fabricated from a metal-inverse-opal structure.

3. The micro-cooler assembly of claim 1, wherein the manifold is fabricated from silicon or polydimethylsiloxane.

4. The micro-cooler assembly of claim 1, wherein the at least one inlet comprises a first inlet and a second inlet that are positioned to provide the liquid on opposite sides of the wick region on the cold plate.

5. The micro-cooler assembly of claim 1, wherein the at least one inlet comprises at least four inlets.

6. The micro-cooler assembly of claim 1, wherein:
the manifold further comprises a bottom surface;
the bottom surface comprises at least one inlet region;
the at least one inlet is fluidly coupled to the at least one inlet region; and
the at least one inlet region comprises a micro-pillar array.

7. The micro-cooler assembly of claim 1, further comprising a heat generating component coupled to a bottom surface of the cold plate opposite the wick region, wherein heat generated by the heat generating component evaporates the liquid within the wick region.

8. A micro-cooler array comprising:
an array of manifolds, each manifold comprising:
a plurality of fins, wherein each fin of the plurality of fins comprises a micro-channel; and
a plurality of vapor gaps interlaced with the plurality of fins;
a central inlet for receiving a liquid centrally disposed within the array of manifolds; and
a cold plate comprising:
an array of wick regions vertically aligned with the array of manifolds; and
an inlet distribution path positioned between individual wick regions of the array of wick regions, wherein the inlet distribution path comprises a plurality of micro-structures,
wherein:
the array of manifolds is coupled to a surface of the cold plate;
the central inlet is operable to provide the liquid to a central location with respect to the array of wick regions;
the liquid is operable to be wicked within the inlet distribution path and into the array of wick regions through the micro-channels of the plurality of fins; and
heating of the liquid changes phase to a vapor that exits the array of manifolds through the plurality of vapor gaps.

9. The micro-cooler array of claim 8, wherein one or more of a width of the micro-channels of the plurality of fins and a width of the plurality of vapor gaps is graded.

10. The micro-cooler array of claim 8, wherein the plurality of micro-structures within the inlet distribution path is functionally graded.

11. The micro-cooler array of claim 8, wherein the cold plate is fabricated from silicon and the array of wick regions is fabricated from a metal-inverse-opal structure.

12. The micro-cooler array of claim 8, wherein the manifold is fabricated from silicon or polydimethylsiloxane.

13. The micro-cooler array of claim 8, further comprising an array of heat generating components coupled to a bottom surface of the cold plate opposite the array of wick regions, wherein heat generated by the array of heat generating components evaporates the liquid within the array of wick regions.

14. The micro-cooler array of claim 13, wherein the array of heat generating components comprises an array of microchips.

15. A micro-cooler array comprising:
an array of manifolds, each manifold comprising:
an inlet manifold;
a plurality of fins, wherein each fin of the plurality of fins comprises a micro-channel and has a right angle shape;
a plurality of vapor gaps interlaced with the plurality of fins; and
a plurality of inlets for receiving a liquid disposed within the array of inlet manifolds of the array of manifolds; and
a cold plate comprising an array of wick regions vertically aligned with the array of manifolds, wherein:
the plurality of inlets is operable to provide the liquid to the array of wick regions;
the liquid is operable to be wicked into the array of wick regions through the micro-channels of the plurality of fins; and
heating of the liquid changes phase to a vapor that exits the array of manifolds through the plurality of vapor gaps.

16. The micro-cooler array of claim 15, wherein one or more of a width of the micro-channels of the plurality of fins and a width of the plurality of vapor gaps is graded.

17. The micro-cooler array of claim 8, wherein the cold plate is fabricated from silicon and the array of wick regions is fabricated from a metal-inverse-opal structure.

18. The micro-cooler array of claim 8, wherein the manifold is fabricated from silicon or polydimethylsiloxane.

19. The micro-cooler array of claim 8, further comprising an array of heat generating components coupled to a bottom surface of the cold plate opposite the array of wick regions, wherein heat generated by the array of heat generating components evaporates the liquid within the array of wick regions.

20. The micro-cooler array of claim 19, wherein the array of heat generating components comprises an array of microchips.
